(19) United States
(12) Patent Application Publication
(10) Pub. No.: US 2015/0243764 A1
(43) Pub. Date: Aug. 27, 2015

(54) METHOD FOR MANUFACTURING A SEMICONDUCTOR STRUCTURE

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Huilong Zhu, Poughkeepsie, NY (US)

(21) Appl. No.: 14/430,337

(22) PCT Filed: Oct. 23, 2012
(86) PCT No.: PCT/CN2012/083337

§ 371 Date: Mar. 23, 2015

(30) Foreign Application Priority Data
Sep. 25, 2012 (CN) 201210362926.6

(51) Int. Cl. H01L 29/66; H01L 29/06; H01L 29/08; H01L 21/84; H01L 21/265; H01L 21/266; H01L 29/167; H01L 21/762

(52) U.S. Cl. CPC H01L 29/66659; H01L 29/167; H01L 29/0653; H01L 21/76224; H01L 21/84; H01L 21/26586; H01L 21/26513; H01L 21/266; H01L 29/0847

(57) ABSTRACT

The present invention discloses a method for manufacturing a semiconductor structure, which comprises the following steps: a) providing an SOI substrate, a shallow trench is formed on the SOI substrate, with the defined area of the shallow trench corresponding to the active region; b) forming the heavily doped layer on the shallow trench sidewall close to the active region; c) filling the shallow trench to form the shallow trench isolation structure; d) forming the semiconductor device in the active region. In the present disclosure, PN junctions are formed in the source electrode and the body region of the SOI, to provide a discharge channel for the charge accumulated in the body region, to reduce the impact of the floating body effect, and to improve the reliability of the device.

### CROSS-REFERENCE TO RELATED APPLICATION

This application claims priority to the Chinese Patent Application No. 201210362926.6, filed on Sep. 25, 2012, entitled “Method for Manufacturing Semiconductor Device”, which is incorporated herein by reference in its entirety.

### TECHNICAL FIELD

The present disclosure relates to the field of semiconductor manufacturing, and in particular, to a method for manufacturing a semiconductor structure.

### BACKGROUND OF THE INVENTION

In order to improve the performance and integration of integrated circuit chips, device feature sizes continue to shrink in accordance with Moore's Law and have reached nano scale currently. With the reduction of device volumes, power consumption and leakage current become the most concerned issue. CMOS device made with SOI (Silicon on Insulator) technology has many advantages such as high speed, low power consumption, high degree of integration, radiation resistance and no self-locking effect etc., and has become the preferred structure for deep sub-micron and nanoscale MOS devices.

Depending on whether the body region is depleted, SOI devices can be classified into two categories: partially depleted and fully depleted. Generally speaking, fully depleted SOI devices have thin top layer silicon film, and threshold voltage is difficult to control for these devices. Therefore, partially depleted SOI devices currently still adopt commonly used and cost-effective solutions. For partially depleted SOI devices, as the body region is not completely depleted, the body region is still in suspended state, and the charge generated by impact ionization cannot be quickly removed, leading to the emergence of floating body effect. For SOI NMOS devices, electron-hole pairs are generated by the impact ionization of channel electrons at the drain end, and then the holes flow to the body region, and accumulate in the body region, raising the potential of the body region, leading to the reduction of the NMOS threshold voltage and the increase in leakage current, hence causing the warping of the device output characteristic curve, which is not beneficial to the performance and reliability of the device and circuit. For PMOS devices, hole ionization rate is lower, and the electron-hole pairs generated by impact ionization are far less than that of NMOS devices, so the impact of floating body effect is weaker.

To resolve the floating body effect, body contact method is usually adopted, to make electrical leads in the body region that are connected to a constant potential (source or ground), providing a discharge channel for the charge accumulated in the body region, and reducing the potential of the body region. However, this generally complicates manufacturing processes, increases device manufacturing costs, and lowers some electrical performances while increasing device area.

### SUMMARY OF THE DISCLOSURE

The purpose of the present disclosure is to at least resolve the above mentioned technical defects, by providing a method to reduce the floating body effect of SOI devices and to improve the performance and reliability of semiconductor devices.

In order to achieve the above objective, the present disclosure provides a method for manufacturing a semiconductor structure, which comprises the following steps:

a) Providing an SOI substrate, a shallow trench is formed on the SOI substrate, with the defined area of the shallow trench corresponding to the active region;
b) Forming the heavily doped layer on the shallow trench sidewall close to the active region;
c) Filling the shallow trench to form the shallow trench isolation structure;
d) Forming the semiconductor device in the active region.

Wherein, the active region adjacent to the sidewall corresponds to source region.

In step (b), the method of forming the heavily doped layer is large angle tilt ion implantation. For NMOS devices, the heavily doped layer is p-doped, and the ion implanted is B or BF₂; for PMOS devices, the heavily doped layer is n-doped, and the ion implanted is P or As.

According to the manufacturing method provided in the present disclosure, PN junctions can be formed in the source electrode and the body region of the SOI, to provide a discharge channel for the charge accumulated in the body region, to reduce the impact of the floating body effect, and to improve the reliability of the device. Meanwhile, since only a one-step process is added to the manufacturing of the shallow trench isolation structure, not affecting the standard semiconductor manufacturing processes, without the need to make electrical leads in the body region, the device area will not be increased.

### BRIEF DESCRIPTION OF THE DRAWINGS

By the detailed description of embodiments with reference to the attached drawings, the above mentioned and/or other additional features and advantages of the present disclosure will become more apparent and easy to understand, wherein:

FIG. 1 is a flowchart of a specific embodiment applying the method for manufacturing a semiconductor structure according to the present disclosure;

FIG. 2 to FIG. 11 are cross-sectional views or overhead views of the semiconductor structure in various stages of its manufacturing process following the method illustrated in FIG. 1.

### DETAILED DESCRIPTION

The embodiment of the present disclosure will be described in detail. The example of the embodiment is presented in the attached drawings, wherein from the start to finish, the same or similar reference numerals refer to the same or similar elements or the elements with the same or similar functions. The embodiment described below by reference to the drawings is exemplary, and only used for explaining the present disclosure, and cannot be considered as limiting the present disclosure. The following disclosure provides many different embodiments or examples to achieve different structures of the present invention. In order to simplify the disclosure of the present invention, the components and settings of a set of specific examples will be described herein. Certainly, they are only examples, and are not to limit the present invention. In addition, the present disclosure may repeat the reference numerals and/or letters in different examples. This repetition is only for simplification and clarity purposes, not indicating any relationship between various embodiments and/or settings discussed. In addition, the present disclosure provides various examples of specific processes and materials, but technical people skilled in the art may appreciate the application and applicability of other processes and/or materials. Further, the structure described below of the first feature “on” the second feature may include the embodiment with the first and second features forming direct contact, and may also include the embodiment with additional features formed between the first and second feature, in which case the first and second features may not be in direct contact.

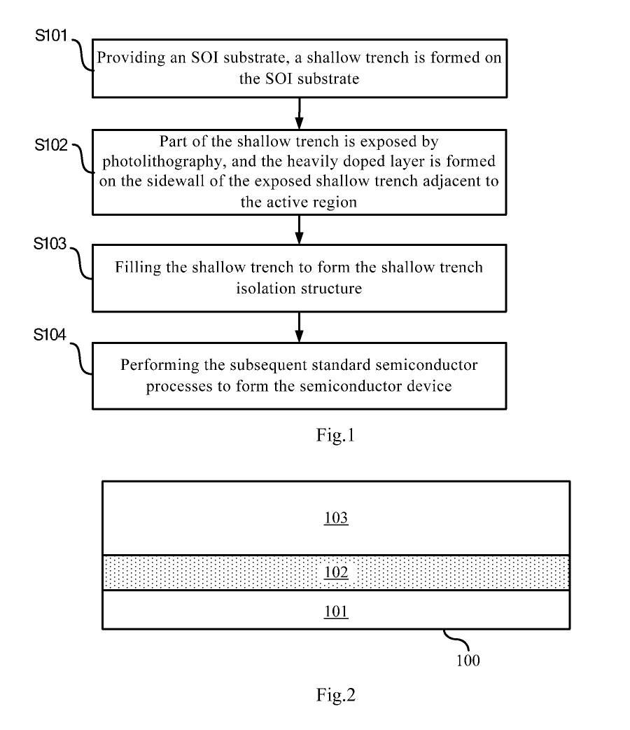

FIG. 1 is a flowchart of the method for manufacturing a semiconductor structure according to the present disclosure. As a specific embodiment of the present disclosure, FIG. 2 to FIG. 11 are cross-sectional views of a semiconductor structure in various stages of its manufacturing process following the flowchart illustrated in FIG. 1. The method of forming a semiconductor structure shown in FIG. 1 will be described in detail with reference to FIG. 2 to FIG. 11. It should be noted that the attached drawings of the embodiment are for illustration purpose only, and are not necessarily drawn in proportion.

Referring to FIG. 2 to FIG. 5, in step S101, providing an SOI substrate 100, a shallow trench 210 is formed on the SOI substrate 100.

First, as shown in FIG. 2, the SOI substrate 100 comprises a base layer 101, an insulating layer 102 located above the base layer 101, and a device layer 103 located above the insulating layer 102.

In the present embodiment, the base layer 101 is monocrystalline silicon. In other embodiments, the base layer 101 may comprise other basic semiconductors such as germanium, or other compound semiconductors, for example, silicon carbide, gallium arsenide, indium arsenide or indium phosphide. Typically, the base layer 101 may have a thickness of about, but not limited to several hundred micrometers, such as a thickness range of 0.2 mm˜1 mm. The insulating layer 102 can be SiO₂, silicon nitride, Al₂O₃ or any other suitable insulating materials. Typically, the insulating layer 102 has a thickness of about 10 nm˜300 nm.

The device layer 103 can be any one of the semiconductors that the base layer 101 comprises. In the present embodiment, the device layer 103 is monocrystalline silicon. In other embodiments, the device layer 103 may comprise other basic semiconductors or compound semiconductors. Typically, the device layer 103 has a thickness of about 10 nm˜100 nm.

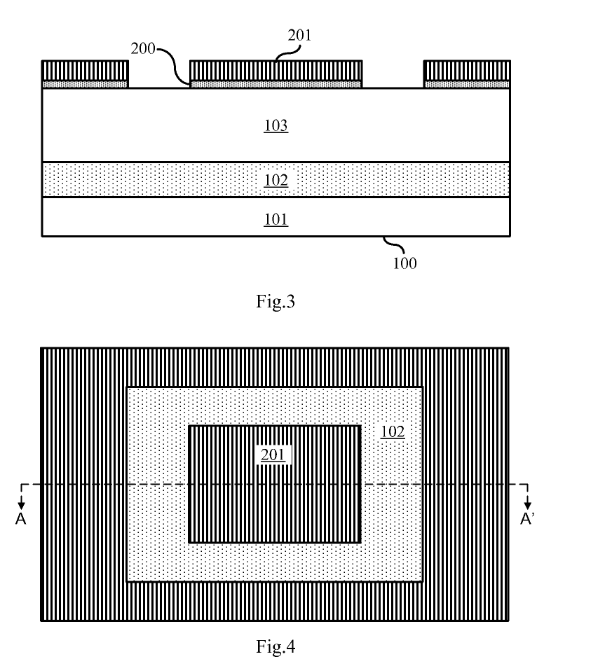

Subsequently, as shown in FIG. 3, a mask layer is formed on the surface of the SOI substrate 100, and then patterning is performing to define the shallow trench pattern. The mask layer may have a multilayer structure. In the present embodiment, the mask layer has a two-layer structure, 200 and 201. The material of the mask layer 200 is silicon oxide and the material of the mask layer 201 is silicon nitride.

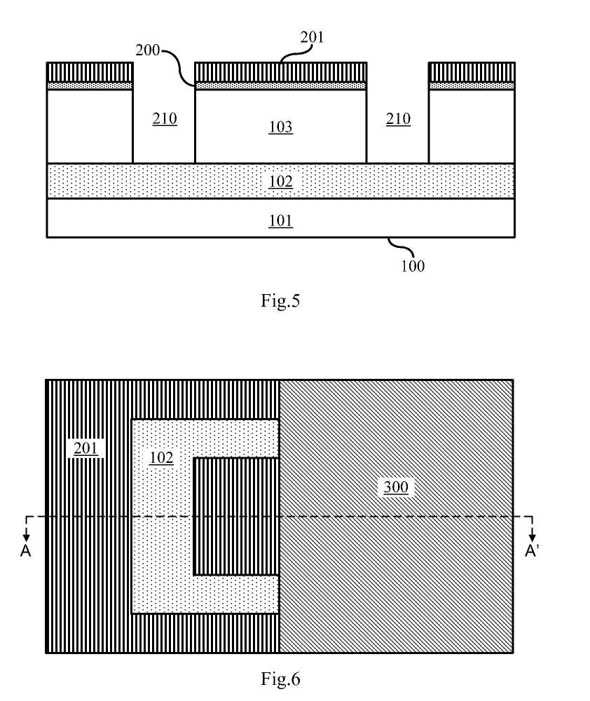

Then, etching of the exposed device layer 103 leads to the formation of a shallow trench 210. The method of etching includes wet etching or RIE dry etching, as shown in FIG. 4. FIG. 5 is the plane overhead view of the structure shown in FIG. 4, where the shallow trench 210 is rectangular, and the enclosed device layer 103 corresponds to the active region, for the manufacturing of semiconductor devices.

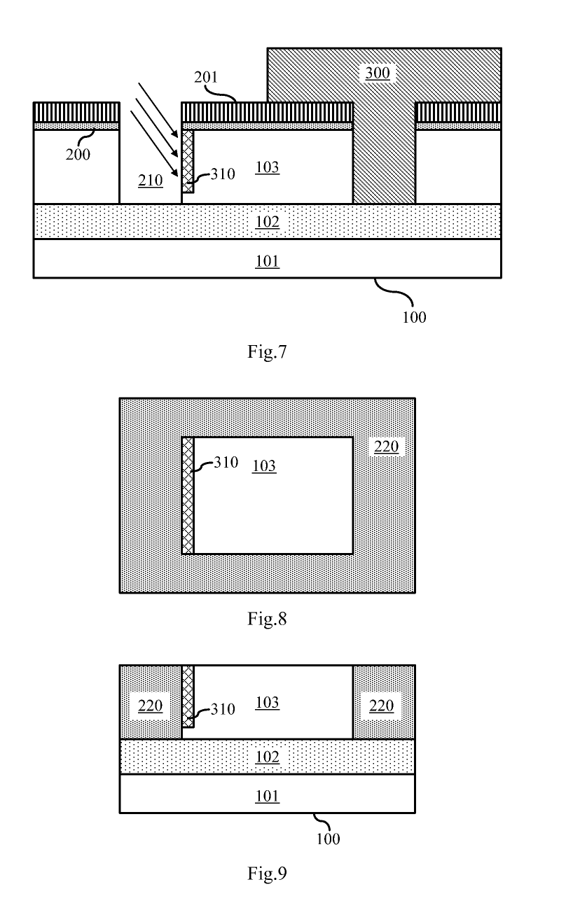

Step S102 is performing Part of the shallow trench is exposed by photolithography, and the heavily doped layer 310 is formed on the sidewall of the exposed shallow trench 210 adjacent to the active region. Wherein, the active region adjacent to the sidewall for formation of the heavily doped layer 310, preferably corresponds to the source region. Preferably, the sidewall is perpendicular to the direction of the length of the channel in the semiconductor device, i.e., the sidewall for formation of the heavily doped layer 310 is located in the active region on one of the end surfaces in the direction of the length of the channel. First, before the formation of the heavily doped layer, a masking layer is used to cover the portion of the semiconductor structure corresponding to the drain region of the semiconductor device. To put this in detail, a masking layer is coated on the SOI substrate, preferably photoresist 300, then patterning is performing to expose part of the shallow trench, as shown in FIG. 6. FIG. 7 is the plane overhead view of the structure shown in FIG. 6, wherein, the device area adjacent to the exposed shallow trench 210 is used for formation of the semiconductor device source region, and the remaining photoresist 300 covers the sidewall adjacent to the drain region for formation of semiconductor devices in the shallow trench. Subsequently, the heavily doped layer 310 is formed on the sidewall of the exposed shallow trench 210 adjacent to the active region. The method of forming the heavily doped layer 310 is large angle tilt ion implantation, wherein the angle for ion implantation is 10°-45°, the implantation energy is less than 1 keV, the implantation dose is greater than 5×10¹⁴ cm⁻², and the peak doping is greater than 7×10¹⁹ cm⁻³. For SOI NMOS devices, the heavily doped layer 310 is p-doped, and the ion implanted is B or BF₂; for PMOS devices, the heavily doped layer 310 is n-doped, and the ion implanted is P or As. The lately formed heavily doped layer 310 is shown in FIG. 6. The length direction of the channel of the transistor to be formed corresponds to the left-right direction in FIG. 6. It can be seen from the figure that the sidewall of the shallow trench 210 where the heavily doped layer 310 is located, is basically perpendicular to the length direction of the channel. It should be noted that “basically perpendicular” means perpendicular within the permitted error range of semiconductor manufacturing processes. As the sidewall of the drain region for the formation of semiconductor devices is protected by photoresist 300, the heavily doped layer cannot be formed on the sidewall of the drain region.

Subsequently, step S103 is performing, the shallow trench 210 is filled to form the shallow trench isolation structure 220. Specifically, first the photoresist 300 that partially fills the shallow trench is removed, then silicon oxide is filled in the shallow trench 210, and lastly chemical mechanical polishing is conducted to remove the mask layer 200 and 201 on the surface, forming the shallow trench isolation structure 220, which is used for electrical isolation of continuous semiconductor devices. The manufacturing of the shallow trench isolation structure 220 can be conducted following standard semiconductor manufacturing processes. FIG. 8 is the cross-sectional view after formation of the shallow trench isolation structure 220, and FIG. 9 is the corresponding plane overhead view. The heavily doped layer 310 is located in the area between the shallow trench isolation structure 220 and the device layer for formation of semiconductor devices.

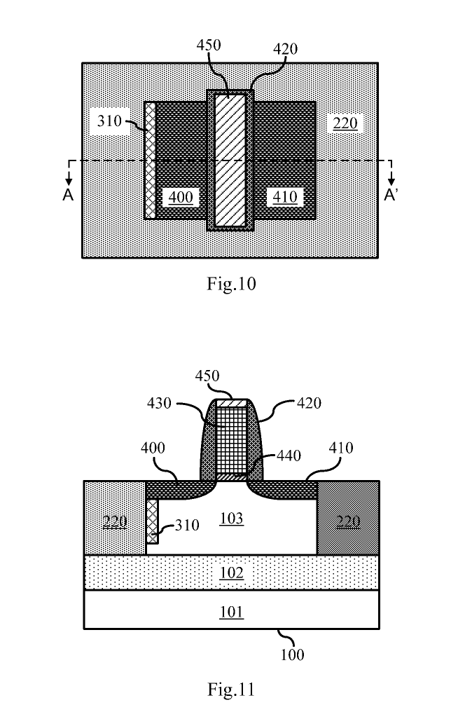

In step S104, the subsequent standard semiconductor processes are performing to form the semiconductor device, which comprises, as shown in FIGS. 10 and 11, formation of the gate stack, source region 400, drain region 410, sidewall 420 and the subsequent electrical contact and passivation processes. The gate stack is formed on the SOI substrate 100, comprising gate dielectric layer 440 and gate 430, especially, also comprising gate covering layer 450. The gate stack, the source region 400, the drain region 410, the sidewall 420 and the subsequent electrical contact and passivation processes can be achieved by standard semiconductor processes, and therefore are not described here. As shown in FIG. 10, the heavily doped layer 310 is underneath the source region 400, forming p+/n+ junctions with the source region, which provide a discharge channel for the charge accumulated in the body region, can reduce the floating body effect of the SOI device and improve the performance and reliability of the device. Furthermore, by formation of PN junctions with the heavily doped layer, the body region is electrically connected to the source electrode, eliminating the need to make electrical leads in the body region and saving the device area.

While the exemplary embodiment and its advantages have been described in detail, it should be understood that without deviating from the spirit of the invention and the scope of protection defined in the appended claims, various changes, substitutions and modifications can be made to these embodiments. For other examples, people skilled in the art should easily understand that without deviating from the scope of protection of the present disclosure, the order of process steps may be changed.

Additionally, the scope of application of the present invention is not limited to the processes, organization, manufacturing, material composition, means, methods and steps described herein for the particular embodiments. From the disclosure of the present invention, people skilled in the art may easily understand, for the processes, organization, manufacturing, material composition, means, methods or steps that are currently existing or to be developed later, they can be used in accordance with the present invention, to execute virtually the same functions as the embodiments described in the present invention or to achieve virtually the same results. Accordingly, the appended claims of the present invention seek to include these processes, organization, manufacturing, material composition, means, methods or steps in the scope of protection.

1. A method for manufacturing a semiconductor structure, which comprises the following steps:
a) providing an SOI substrate, a shallow trench is formed on the SOI substrate, with the defined area of the shallow trench corresponding to the active region;
b) forming a heavily doped layer on a sidewall of the shallow trench close to the active region;
c) filling the shallow trench to form the shallow trench isolation structure;
d) forming the semiconductor device in the active region.

2. The method according to claim 1, in step b), the active region adjacent to the sidewall corresponds to the source region.

3. The method according to claim 2, the sidewall is perpendicular to the direction of the length of the channel in the semiconductor device.

4. The method according to claim 1, in step b), the heavily doped layer is formed by large angle tilt ion implantation.

5. The method according to claim 4, the angle for the large angle tilt ion implantation is 10° ˜45°.

6. The method according to claim 4, wherein, the implantation energy is less than 1 keV, the implantation dose is greater than 5×1014 cm-2, and the peak doping is greater than 7×1019 cm-3.

7. The method according to claim 1, in step b), before the formation of the heavily doped layer, a masking layer is used to cover the portion of the semiconductor structure corresponding to the drain region of the semiconductor device.

8. The method according to claim 1, in step b), for NMOS devices, the heavily doped layer is p-doped, and the ion implanted is B or BF2; for PMOS devices, the heavily doped layer is n-doped, and the ion implanted is P or As.

9. The method according to claim 2, in step b), for NMOS devices, the heavily doped layer is p-doped, and the ion implanted is B or BF2; for PMOS devices, the heavily doped layer is n-doped, and the ion implanted is P or As.

10. The method according to claim 3 in step b), for NMOS devices, the heavily doped layer is p-doped, and the ion implanted is B or BF2; for PMOS devices, the heavily doped layer is n-doped, and the ion implanted is P or As.

11. The method according to claim 4 in step b), for NMOS devices, the heavily doped layer is p-doped, and the ion implanted is B or BF2; for PMOS devices, the heavily doped layer is n-doped, and the ion implanted is P or As.

12. The method according to claim 5 in step b), for NMOS devices, the heavily doped layer is p-doped, and the ion implanted is B or BF2; for PMOS devices, the heavily doped layer is n-doped, and the ion implanted is P or As.

13. The method according to claim 6 in step b), for NMOS devices, the heavily doped layer is p-doped, and the ion implanted is B or BF2; for PMOS devices, the heavily doped layer is n-doped, and the ion implanted is P or As.

14. The method according to claim 7 in step b), for NMOS devices, the heavily doped layer is p-doped, and the ion implanted is B or BF2; for PMOS devices, the heavily doped layer is n-doped, and the ion implanted is P or As.
